(19) United States
(12) Patent Application Publication
(10) Pub. No.: US 2016/0020388 A1
(43) Pub. Date: Jan. 21, 2016

(54) Resistive switching by breaking and re-forming covalent bonds

(71) Applicants: Intermolecular Inc., San Jose, CA (US); Kabushiki Kaisha Toshiba, Tokyo (JP); SanDisk 3D LLC, Milpitas, CA (US)

(72) Inventor: Yun Wang, San Jose, CA (US)

(21) Appl. No.: 14/336,830

(22) Filed: Jul. 21, 2014

(51) Int. Cl. H01L 45/00

(52) U.S. Cl. CPC H01L 45/08; H01L 45/1233; H01L 45/145; H01L 45/1625; H01L 45/1616

(57) ABSTRACT

A variable resistance layer in a resistive non-volatile memory (ReRAM) cell changes its resistance in response to an applied signal by breaking and re-forming covalent bonds (e.g., in sub-stoichiometric silicon oxide). Resistivity decreases with increasing density of broken “dangling” bonds. When an electric field is applied, more dangling bonds are created, forming a filament of defects through which charge carriers can tunnel through the covalent layer. Passing a high current through the dangling-bond filament causes localized heating that re-forms the bonds. Optionally, an ionic oxide or nitride layer in contact with the covalent switching layer may serve as an oxygen source for thermal re-oxidation during the heating.

### BACKGROUND

Related fields include semiconductor devices and their fabrication; in particular, thin-film components of resistive-switching non-volatile memory (ReRAM).

Nonvolatile memory elements are used in computers and other devices requiring persistent data storage (e.g., cameras, music players). Some traditional nonvolatile memory technologies (e.g., EEPROM, NAND flash) have proven difficult to scale down to smaller or higher-density configurations. Therefore, a need has developed for alternative nonvolatile memory technologies that can be scaled down successfully in terms of performance, reliability, and cost.

In resistive-switching-based nonvolatile memory, each individual cell includes a bistable variable resistor. It can be put into either of two states (low-resistance or high-resistance), and will stay in that state until receiving the type of input that changes it to the other state (a “write signal”). The resistive state of the variable resistor corresponds to a bit value (e.g., the low-resistance state may represent logic “1” and the high-resistance state may represent logic “0”). The cell is thus written to by applying a write signal that causes the variable resistor to change resistance. The cell is read by measuring its resistance in a way that does not change it. Preferably, write and read operations should require as little power as possible, both to conserve energy and to avoid generating waste heat.

Many ReRAM devices change resistance by creating and destroying, or lengthening and shortening, one or more conductive paths through a variable-resistance layer or stack while the bulk material remains static (e.g., it does not change phase). The bulk material is often a highly insulating dielectric. The conductive paths (also known as “percolation paths”) are formed when an electric field organizes conductive or charged defects or impurities into a filament stretching from one interface to the other, with sufficient defect density that charge carriers can easily traverse the layer by tunneling from defect to defect. To return the variable resistor to the high-resistive state, it is often not necessary to destroy the entire filament, but only to introduce a gap too wide for tunneling somewhere along the filament's length. Some of the types of defects that have been used include metal clusters and oxygen (or nitrogen) vacancies.

The “forming process” that creates the very first filament in a newly fabricated ReRAM cell is risky. The defects may be randomly scattered through the bulk of the variable-resistance layer, or they may be in some other layer such as an electrode or other source layer. Some cells may need stronger electric fields than others to collect the defects into a filament because the initial defect distributions may vary from cell to cell. Substantial force is necessary to push impurity atoms through a solid (e.g., metal, oxygen, or nitrogen) or break ionic bonds typical of high-ionicity materials such as hafnium oxide (HfOₓ) and other “high-k” dielectrics (having a dielectric constant greater than 9). The risk is of “over-forming;” creating a filament so wide or dense that the operating write signals are too weak to break it. An over-formed cell cannot be rewritten. At this point the entire device has been built, so the investment has been significant and the cost of failure is high.

Therefore, a need exists for a resistive-switching non-volatile memory cell that operates at lower power and does not require a forming field strength so high as to be potentially damaging.

### SUMMARY

The following summary presents some concepts in a simplified form as an introduction to the detailed description that follows. It does not necessarily identify key or critical elements and is not intended to reflect a scope of invention.

Embodiments of a resistive-switching nonvolatile memory cell that changes resistance by breaking and re-forming covalent bonds may include a first conductive layer that functions as a first electrode, a second conductive layer that functions as a second electrode, a variable-resistance layer including covalent-bonded material (the “covalent layer”) that reversibly changes resistance when a write signal is applied, and an optional layer including ionic-bonded material (the “ionic layer”) that prevents interaction with reactive electrode and may form a static section of a filament.

The first conductive layer and the second conductive layer may be single layers or stacks. One or both of the conductive layers may also function as an embedded resistor. One of the conductive layers may also function as an oxygen getter.

The variable-resistance layer may be a single layer, a bi-layer including a covalent layer and an ionic layer, or a stack including interface layers such as barrier, adhesion, doping, capping, or work-function layers. The covalent layer may be silicon oxide, silicon nitride, or silicon oxynitride; may be locally heated (e.g., near an interface) to between 500C and 900C during reset; may include covalent silicon-silicon bonds; may be amorphous after annealing; may be sub-stoichiometric; or may be between 5 nm and 10 nm thick for low leakage comparable to a thinner SiO₂ layer.

The optional ionic layer may be a “high-k” material with a dielectric constant >9. may have a stoichiometric composition, or may be crystalline after annealing. The optional ionic layer may be an oxide or oxynitride (e.g., a transition metal oxide or a transition metal oxynitride) if the covalent layer is an oxide or oxynitride, or may be a nitride if the covalent layer is a nitride. The ionic layer may be adjacent to the interface where the covalent layer is locally heated to break the filament duing reset.

Embodiments of methods of fabricating a resistive-switching nonvolatile memory cell that changes resistance by breaking and re-forming covalent bonds may include forming a first conductive layer over a substrate, forming a variable-resistance layer over the first conductive layer, optionally forming a high-ionicity layer over the variable-resistance layer, and forming a second conductive layer over the variable-resistance layer or the optional high-ionicity layer.

The process of forming the conductive layers may include physical vapor deposition (PVD), chemical vapor deposition (CVD), atomic layer deposition (ALD), electrodeposition, evaporation, or any other suitable deposition method for the materials being used. The optional process of forming a high-ionicity layer may include PVD, CVD, ALD, or any other suitable deposition method for the material being used.

The process of forming the covalent variable-resistance layer may include PVD at a substrate temperature between 400C and 520C (e.g., reactive sputtering from a silicon target in an oxygen-containing ambient or co-sputtering from a silicon target and a silicon-oxide target in an inert-gas ambient). Alternatively, it may include PECVD at a substrate temperature between 200C and 270C (e.g., using a 30-35 MHz RF plasma, a 3-to-5 sccm flow rate of silane, and an 18-to 22-sccm flow rate of nitrous oxide). Alternatively, it may include electron-beam evaporation at a substrate temperature between 100C and 150C; or may include rapid thermal annealing of amorphous silicon in an oxygen-containing ambient (e.g., heating the substrate to between 520C and 620C for between 30 seconds and 30 minutes).

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A and 1B conceptually illustrate initial filament formation in the variable-resistance layer of a ReRAM cell.

FIG. 2 is an example I-V plot for reading and writing a ReRAM cell.

FIGS. 3A-G conceptually illustrate resistance change by breaking and re-forming covalent bonds.

FIGS. 4A and 4B conceptually illustrate oxygen-vacancy filament behavior in a switching bi-layer, as a point of reference.

FIGS. 5A and 5B conceptually illustrate the effect of annealing on a crystalline/amorphous bi-layer.

FIG. 6 is a flowchart of an example method for making a ReRAM cell with a covalent switching layer.

FIG. 7 is a block diagram of co-sputtering in an example PVD chamber.

FIG. 8 is a block diagram of an example of a PECVD chamber.

FIG. 9 is a block diagram of an example of an electron-beam evaporation tool.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

As used herein, the following terms shall have the following meanings unless associated text or context indicates an exception:

“A,” “an,” and singular nouns: May include plural variations, e.g., “a layer” may mean “one or more layers.”

“About” or “approximately”: Within ±10% variation.

“Above” and “over”: Either directly contacting or separated by intervening elements; may conform to an underlying 3D structure.

“Amorphous”: Exhibits less than 30% crystallinity as measured by a technique such as x-ray diffraction (XRD).

“Between” (range of values): Both boundary values and any value between the boundaries can be within the scope.

“Conductive:” Resistivity <1e-5 Ω·m at the intended operating temperature.

“Covalent” (material): at least 55% of the bonds in the material are covalent.

“Crystalline”: Exhibits at least 30% crystallinity as measured by a technique such as x-ray diffraction (XRD).

“Dangling bond”: Unsatisfied valence on an atom in a material or layer.

“Film” and “layer”: Interchangeably describe a portion of a stack; may include multiple sub-layers (e.g., a nanolaminate).

“First,” “second,” and other ordinals: For differentiation only, rather than imposing any specific spatial or temporal order.

“High-k material,” “high-k layer,” “high-k dielectric” (interchangeable): A material or layer with a dielectric constant (“k”) greater than 9.

“Inert gas”: Includes noble gases (He, Ne, Ar, Kr, Xe) and, unless the text or context excludes it (e.g., by describing nitride formation as undesirable), nitrogen (N₂).

“Insulating” or “dielectric”: Resistivity >1e8Ω·m at the intended operating temperature.

“Ionic” (material): At least 55% of the bonds in the material are ionic.

“On”: Directly contacting; may conform to an underlying 3D structure.

“Operable” (for a specific purpose): Would satisfactorily fulfill that purpose given suitable connections, signals, or other external conditions.

“Or” in a list: Any, all, or any subset of list may be used.

“Oxide” (of an element): May include additional components besides the element and oxygen, including but not limited to a dopant or alloy.

“Substantially”: Within up to ±5% variation.

“Substrate”: A wafer or any other workpiece on which formation or treatment of material layers is desired. Non-limiting examples include silicon, germanium, silica, sapphire, zinc oxide, SiC, AIN, GaN, Spinel, silicon on oxide, silicon carbide on oxide, glass, gallium nitride, indium nitride and aluminum nitride, glasses, combinations or alloys thereof, and other solid materials.

“Surface”: Boundary between the ambient environment and a feature of the substrate.

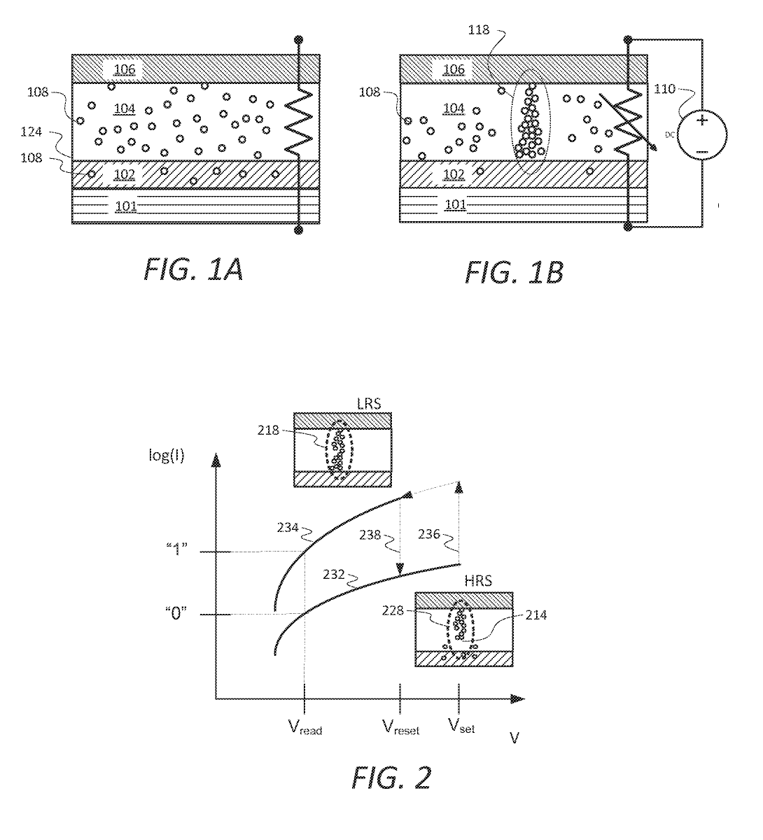

FIGS. 1A and 1B conceptually illustrate initial filament formation in the variable-resistance layer of a ReRAM cell. FIG. 1A is a schematic representation of layers in a ReRAM cell before any filaments are formed. Although some ReRAM cells include additional layers, the illustration is simplified to show only substrate 101 (which may include other structures and layers), electrodes 102 and 112, and VR layer 106 between the electrodes. Electrodes 102 and 112 are generally conductive layers, although the conductivity may sometimes be less than that of typical electrodes in other devices. In such embodiments, a current-limiting embedded resistor may be integrated with one or both of the electrodes to prevent over-forming.

In this example, first electrode 102 is a reactive or “source” electrode that may act as a source or reservoir of electrically active defects 108. In this example, second electrode 112 is an inert electrode that does not react with, or exchange material or defects with, VR layer 106. In some embodiments, the first electrode may be inert and the second electrode may be reactive. Inert electrodes may be made of inert materials (e.g., noble metals) or may be rendered inert by a barrier layer between the electrode and the VR layer (e.g., polycrystalline silicon with a silicon oxide barrier layer). Reactive electrodes may be made of any sufficiently conductive material that provides the desired mobile defects; for example, titanium nitride for oxygen vacancies, or silver or copper for metal ions.

Defects 108 may travel through “reactive interface” 126 between reactive electrode 102 and VR layer 106, e.g., when mobilized by an electric field from an applied voltage. Defects 108 may be, by way of non-limiting example, metal ions, vacancies (e.g., oxygen vacancies), interstitial atoms, or stress-induced lattice dislocations. Either alternatively or in addition, VR layer 106 may be formed with defects 108. If sufficient defects to form a filament are available in VR layer 106, both electrodes may be inert electrodes. VR layer 106 may be a high-k or low-k dielectric, a dielectric stack or, in some embodiments, a low-conductivity semiconductor. With no filament formed, the position, number, and distribution of defects 108 is not conducive to electron tunneling between first electrode 102 and second electrode 112.

In FIG. 1B, a voltage source 110 applies a forming-voltage pulse to electrodes 102 and 112, mobilizing defects 108 to form a filament 118 in VR layer 106. The defects may be gathered from an original distribution throughout the bulk of VR layer 106, or they may enter VR layer 106 from a reactive electrode 102 (or some other type of defect-access layer), or they may be created in VR layer 106 by interaction of the electric field with another feature of the material, or any combination. In filament 118, the defects are sufficiently close together that electrons may tunnel from defect to defect through the VR layer from one electrode to the other. In some embodiments, the forming operation includes heating to enhance mobility of the defects within ReRAM cell 100.

In general, the forming operation is a one-time fabrication step that converts the original dielectric of VR layer 106 to a variable resistive material. Afterward, in operating the ReRAM cell, a lesser “reset” voltage may be applied to break at least the weak part of the filament and raise the resistance of the VR layer to a high resistance state (HRS); a lesser “set” voltage may be applied to restore the broken part of the filament and lower the resistance of the VR layer to a low resistance state (LRS); and an even lesser “read” voltage may be applied to sense the resistance of the VR layer without changing it. Moving, creating, or destroying the defects requires energy, but leaving them in place does not; therefore, the VR layer is non-volatile, retaining its written LRS or HRS state if the cell is unpowered. In some embodiments, the resistance values of the HRS and LRS are repeatable within ±20% or less.

FIG. 2 is an example I-V plot for reading and writing a ReRAM cell. Specifically, FIG. 2 is a plot of current passing through a unipolar ReRAM cell as a function of applied voltage according to some embodiments. The cell's response when the VR layer is in its HRS, with a broken filament 228, is plotted as curve 232. The cell's response when the VR layer is in its LRS, with a restored filament 218, is plotted as curve 234.

With two possible resistive states, the cell can store one bit of data. Some ReRAM cells may have three or more resistance states to enable multi-bit storage in a single cell. To change the stored value, a write voltage V_{SET} or V_{RESET} is applied to the cell. V_{RESET} breaks complete filament 218 at some break point 214 into broken filament 228, and V_{SET} restores broken filament 228 to a complete filament 218. In a unipolar cell as illustrated here, V_{SET} and V_{RESET} have the same polarity. In a bipolar cell, V_{SET} and V_{RESET} have opposite polarities.

To read the stored value, a sensing or “read” voltage V_{READ} is applied across the cell and the output current is measured. Because of Ohm's law, V=IR, for a given V_{READ} the output current I depends on the cell resistance R, which depends on whether the VR layer is in its LRS or its HRS. In the illustrated example, the LRS corresponds to logic “1” and the HRS corresponds to logic “0,” although some embodiments may reverse the correspondences.

ReRAM cells may be switched between LRS and HRS (rewritten) many times. Between switching events, any number of read operations may be performed. In some embodiments, the set voltage (V_{SET}) is between about 100 mV and 10V; e.g., between about 500 mV and 5V. The length of set voltage pulses (t_{SET}) may be less than about 100 milliseconds, less than about 5 milliseconds, or less than about 100 nanoseconds. The read voltage (V_{READ}) may be between about 1/10 and ½ of V_{SET}. In some embodiments, the currents sensed during read operations are greater than about 1 mA, or even greater than about 5 mA to allow for a fast detection of the logic state by small sense amplifiers. The length of a read voltage pulse (t_{READ}) may be comparable to the length of a set voltage pulse (t_{SET}) or may be shorter. ReRAM cells preferably can switch between LRS and HRS at least about 10³ times or, more desirably at least about 10⁷ times without failure. They preferably retain their data for at least about 5 years or, more desirably, at least about 10 years at temperatures up to 85° C. under constant application of V_{READ}. In some embodiments, low current leakage, such as less than about 40 A/cm² measured at 0.5 V per 20 Å of oxide thickness in HRS, may also be preferred.

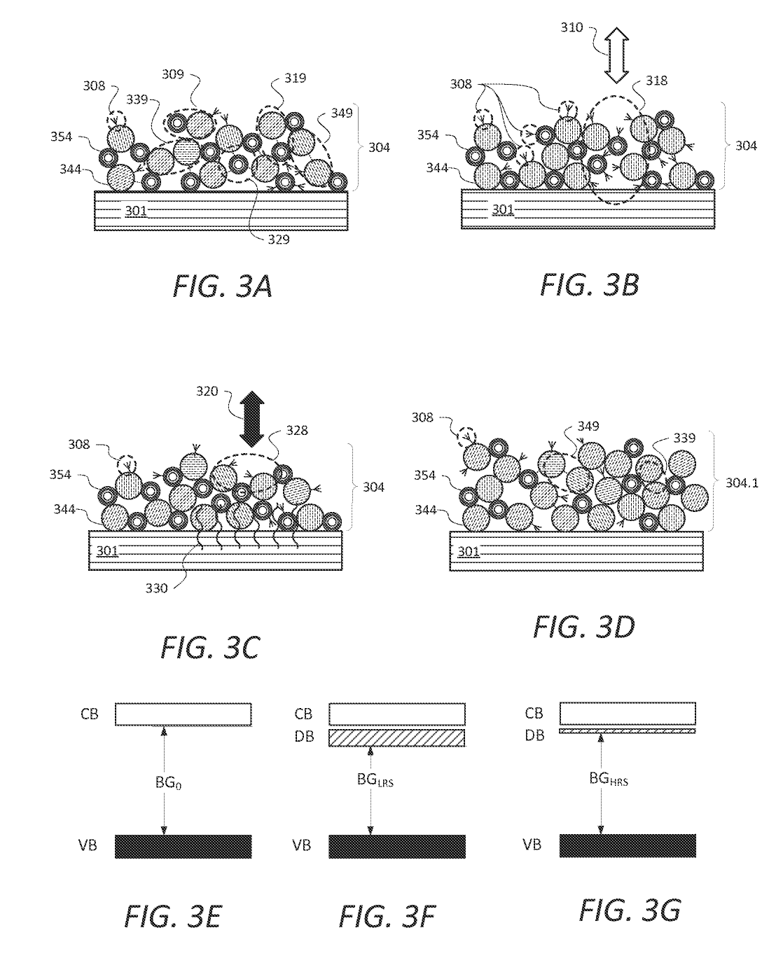

FIGS. 3A-G conceptually illustrate resistance change by breaking and re-forming covalent bonds. FIGS. 3A-C illustrate how forming and reset affect the material structure. Note that these drawings are symbolic depictions of 3-D effects in 2 dimensions; they are not realistic reproductions of any actual material.

In FIG. 3A, substrate 301 may include an electrode. Covalent variable-resistance layer 304 is an amorphous covalent oxide; for ease of discussion, it will be referred to as the non-limiting example of silicon oxide (SiO2) that is amorphous; for example, SiO2 may be amorphous if formed (e.g., deposited and processed) at a temperature well below its crystallization temperature. Si atoms 344 and oxygen atoms 354 are arranged somewhat randomly. As a result, along with strong Si—O bonds 309, there are weak or strained Si—O bonds 319, weak shared Si—O bonds 329, strong Si—Si bonds 339, weak or strained Si—Si bonds 349, and dangling bonds (unsatisfied bonding sites) 308. Dangling bonds 308 are the defects that will make the conductive paths through VR layer 304, instead of (or besides) metal clusters and/or oxygen vacancies.

In FIG. 3B, an electric field 310 forces dipoles in the material toward an aligned state. This may cause weak bonds to break apart or shared bonds to become single bonds, resulting in an increase in the number of dangling bonds. A filament 318 is formed on the path of least resistance, lowering the resistance of VR layer 304. A forming or set signal may provide the electric field 310 to form additional dangling bonds in covalent VR layer 304 and put the ReRAM cell into its LRS.

In FIG. 3C, another electric field 320 produces a concentrated current through filament 318, causing localized heating 330. The heating produces a “micro-annealing” event that allows the atoms to rearrange themselves into lower-energy states. This causes some of the dangling bonds to re-orient and couple with neighboring dangling bonds, re-forming covalent Si—O or Si—Si bonds and reducing dangling-bond filament 318 to broken dangling-bond filament 328. The elimination of part of the filament increases the resistance of VR layer 304. A reset signal may dissipate or otherwise provide the localized heat to reduce the number of dangling bonds in covalent VR layer 304 and put the ReRAM cell into its HRS.

The local temperature produced by heating 330 depends on (1) the localized current density, which to first order is the reset current and divided by the local cross-sectional area of the filament, (2) the thermal properties, such as thermal conductivity, of the material (or materials, if the localized heating is at an interface between two materials), and (3) the length of the reset pulse. It is often possible to see and measure the width of a filament in a sectioned ReRAM cell by scanning electron microscopy (SEM), tunneling electron microscopy (TEM), atomic force microscopy (AFM), or the like. Knowledge of the material(s) and the reset current pulse characteristics can then facilitate thermal modeling to calculate the localized temperature as a result of heating by the reset pulse. In some embodiments, this temperature is between 500C and 900C.

In some embodiments, the heating may also drive some oxygen into the covalent layer from an adjacent layer, which also tends to passivate the dangling bonds. Some embodiments may combine the action of some dangling bonds and some oxygen vacancies for switching.

Covalent materials are well-suited to dangling-bond-based resistive switching because less power is required to break covalent bonds than to break ionic bonds or push interstitial atoms many atomic diameters through a solid material. In some embodiments, the composition may be adjusted to manipulate the initial number of dangling bonds and the relative prevalence of different types of bonds.

FIG. 3D illustrates the effect of composition on the baseline number of dangling bonds. The SiOₓ layer 304 in FIGS. 3A-C had sufficiently high oxygen content that Si—O bonds dominated and Si—Si bonds were a small minority. By contrast, the SiOₓ layer 304.1 in FIG. 3D has much less oxygen. A sub-stoichiometric, oxygen-starved composition not only has more intrinsic dangling bonds 308, but also has a greater proportion of Si—Si bonds than a near-stoichiometric or stoichiometric composition with more oxygen. This is significant because Si—Si bonds can be broken with less energy than Si—O bonds, possibly lowering the required operating power.

A consequence of the increased Si/SiOₓ ratio and the increase in intrinsic dangling bonds, however, is an overall lowered resistivity for the variable-resistance layer. It may be desirable for a variable-resistance layer to have low leakage current while in the LRS. Therefore, to achieve the same leakage current density value J_{g}, a sub-stoichiometric covalent SiOₓ layer for dangling-bond switching needs to be thicker than a stoichiometric or near-stoichiometric SiO₂ layer for some other type switching, such as metal-cluster or oxygen-vacancy switching. Specifically, the sub-stoichiometric covalent layer for dangling-bond switching may be on the order of 5-10 nm thick, compared to the 1-5 nm thickness of stoichiometric SiO₂ for pure oxygen-vacancy switching.

FIGS. 3E-G are energy band diagrams corresponding to different states of a covalent switching layer. FIG. 3E represents the energy bands of an “ideal” dielectric material with no defects. Bandgap BG₀ extends from valence band VB to conduction band CB, presenting a substantial obstacle to migration of charge carriers. FIG. 3F represents the energy bands of a dangling-bond-switching covalent material in its LRS, after an electric field has increased the number of dangling bonds. Defect “mini-band” DB is between valence band VB and conduction band CB, reducing the bandgap to BG_{LRS}, which presents less of an obstacle to charge carriers. FIG. 3F represents the energy bands of a dangling-bond-switching covalent material in its HRS, after heat has decreased the number of dangling bonds. Defect “mini-band” DB is still between valence band VB and conduction band CB, but it is thinner. Thus the bandgap is increased to BG_{HRS}, which may not be as wide as BG₀ but produces a measurably higher resistance than BG_{LRS}.

Like oxygen-vacancy-switching amorphous or low-ionicity materials, dangling-bond-switching covalent materials can be paired with a high-ionicity layer to form a switching bi-layer.

ReRAM electrodes may be made from conductive materials, such as copper, n-doped polysilicon, p-doped polysilicon, titanium nitride, ruthenium, iridium, platinum, tantalum nitride, tungsten, tungsten nitride, and metal silicon nitrides. Electrodes may be less than about 100 nm thick, less than about 50 nm thick, or even less than about 10 nm thick. Even thinner electrodes may be made by ALD. Either or both electrodes may be made of an inert material that does not react with neighboring layers.

In some embodiments, one of the electrodes may be made of a reactive material to act as a source, reservoir, or sink for defects in the variable resistance layer. Defects may travel through the interface between the reactive electrode and the VR layer during forming, set, or reset operations. For example, titanium nitride is an oxygen-scavenging material and can create oxygen vacancies in a neighboring oxide layer. An oxygen-scavenging electrode may be used with a covalent-bonding oxide switching layer to extract oxygen and help create dangling bonds during the set operation.

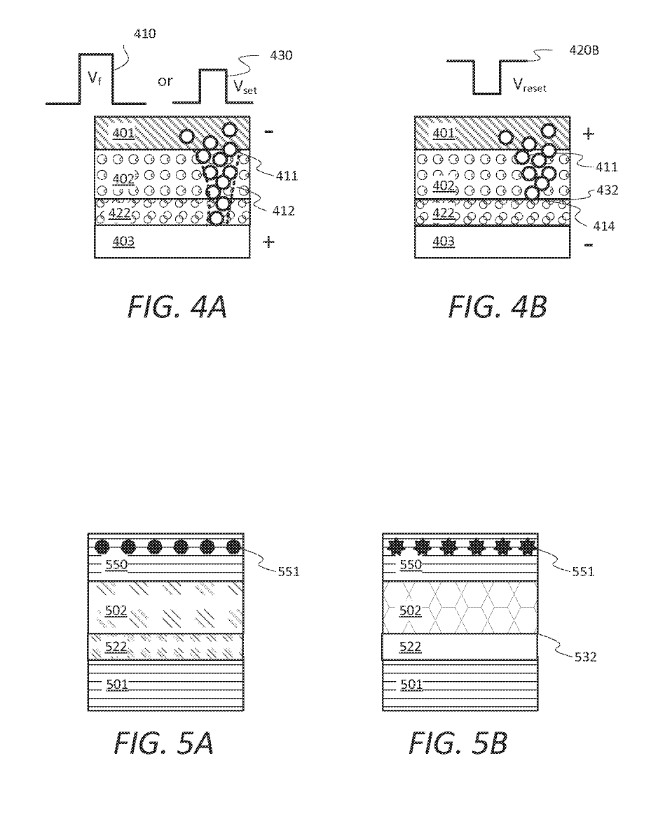

FIGS. 4A and 4B conceptually illustrate oxygen-vacancy filament behavior in a switching bi-layer, as a point of reference. In FIG. 4A, forming pulse 410 or set pulse 430 has been applied. This pulse drives oxygen-vacancy defects 411 from source electrode 401 into high-ionicity layer 402, which readily accepts them and, depending on the high-ionicity material, may add some of its own vacancies. Because most of the path for filament 412 is through high-ionicity layer 402, the stack takes advantage of the easy filament formation of the high-k material in the high-ionicity layer. The formation of filament 412 slows when it encounters the defect-resistant low-ionicity layer, which acts as a brake to prevent overshoot and possible damage to inert electrode 403. The filament may be thinner or more tapered in low-ionicity layer 422 than it would have been in a similar thickness of high-ionicity layer 402 or another layer of a different high-ionicity high-k material.

The division of voltage between high-ionicity layer 402 and low-ionicity layer 422 depends on the layers' relative resistivity. Physical thickness, dielectric constant (k), and the density of vacancies or other defects all influence the relative resistivity. Since low-ionicity layer 422 is selected for low k and low defect density, it has a high effective oxide thickness (EDT) despite its small physical thickness. Therefore, most of the total voltage applied to the stack by forming, set, or reset may be localized to low-ionicity layer 422. Thus the strongest electric field may be concentrated, and the most heat dissipated, in low-ionicity layer 422.

In FIG. 4B, a reset pulse 420B has been applied. The high dielectric constant and/or small number of vacancies in low-ionicity layer 422 confines the electric field and heat from reset pulse 420B to easily destroy that part of the filament, thus taking advantage of the properties of the low-k material in low-ionicity layer 422. Because of the discontinuity at the interface between the low-ionicity and high-ionicity layers, and the greater conductivity of the high-ionicity layer, the reset pulse can apply sufficient field strength and heat to destroy the part of the filament in the low-ionicity layer with little to no effect on the part of the filament in the high-ionicity layer. The next set pulse only has to reconstitute the part of the filament in thin low-ionicity layer 422. Thus, high-ionicity layer 402 now acts as a “virtual electrode.” The actual switching behavior occurs in low-ionicity layer 422, with the advantages of low operating power and good data retention.

Because of the difference in properties between the high-ionicity and low-ionicity switching layers (e.g., ionic vs. covalent, crystalline vs. amorphous, high-k vs. low-k), filament break-point 414 naturally occurs at the bi-layer interface 432. By contrast, break-point 214 in FIG. 2 may form anywhere in the bulk of the single switching layer, and may not be repeatable or consistent from cell to cell. This uncertainty may add noise to the reading of the stored data.

In some embodiments, the discontinuity in dielectric constant, ionicity, or lattice structure at the bi-layer interface may be sufficient to produce the repeatable break-point and localization of heat and electric field in the low-ionicity layer, even if both layers are crystalline (e.g., with different lattice structures and a discontinuity at the interface), or if both layers are amorphous, or if one or both layers are partially crystallized, or if one layer has a higher crystallinity temperature than the other.

In a ReRAM cell that switches by breaking and re-forming covalent bonds, a bi-layer also provides a predictable filament break point at the interface, but the role of the ionic layer (e.g., a high-k crystalline dielectric such as a transition metal oxide) may be different than in oxygen-vacancy switching systems. The ionic oxide layer can serve as a source of oxygen for thermal re-oxidation during the reset process. The interface between the covalent layer and the ionic layer may serve as the origin of the localized heating that re-forms the covalent bonds during reset.

If the covalent layer is an oxide or oxynitride, the ionic layer may be an oxide. Alternatively, both the covalent layer and the ionic layer may be nitrides. Suitable materials for ionic oxide layer include high-k oxides and nitrides. Examples include hafnium oxide (HfₓO_{y}), tantalum oxide (TaₓO_{y}), aluminum oxide (AlₓO_{y}), lanthanum oxide (LaₓO_{y}), yttrium oxide (YₓO_{y}), dysprosium oxide (DyₓO_{y}), ytterbium oxide (YbₓO_{y}), zirconium oxide (ZrₓO_{y}), titanium oxide (TiOₓ), nickel oxide (NiOₓ), cerium oxide (CeOₓ), and nitrides of the same elements.

While sub-stoichiometric high-k layers are sometimes favored for VR layers and bi-layers used in oxygen-vacancy switching, stoichiometric composition may be preferred in some embodiments of an ionic layer used in dangling-bond switching because (1) a stoichiometric composition has more oxygen to contribute to thermal re-oxidation and (2) a stoichiometric composition is more insulating, so it will dissipate more localized heat in response to a reset current concentrated at the adjacent end of a conductive filament.

FIGS. 5A and 5B conceptually illustrate the effect of annealing on a crystalline/amorphous bi-layer. FIG. 5A represents the stack and surrounding elements before the highest-temperature treatment that follows the creation of the bi-layer in the device fabrication process. Substrate 501 may have multiple other layers including electrodes, barriers, embedded resistors, and the like. Low-k dielectric layer 522 is created (deposited, grown, implanted, etc.) over substrate 501. High-k dielectric layer 502 is created over low-k dielectric layer 522. Alternatively, the order of creating high-k dielectric layer 502 and low-k dielectric layer 522 may be reversed. Overlayers 550 are created over the uppermost of dielectric layers 502 and 522. Overlayers 550 may have multiple other layers including electrodes, barriers, embedded resistors, and the like. Some of the substrate layers, dielectric layers, or overlayers may be shaped, patterned, or textured, or otherwise processed into localized structures.

In some ReRAM devices, the highest-temperature treatment is the 750C anneal of the current-steering element to activate one or more dopants. In FIG. 5A, unactivated dopants 551 are included in overlayers 550.

FIG. 5B shows the stack after the highest-temperature treatment. Dopants 551 have been activated. High-k layer 502 has crystallized. Low-k layer 522 is amorphous. Therefore, any current passing through dielectric layers 502 and 522 will encounter a structural discontinuity in the crystalline lattice at bi-layer interface 532, as well as a discontinuity in dielectric constant. This provides a controllable, repeatable break-point for the filament. Both oxygen-vacancy and dangling-bond switching cells can benefit from a difference in crystallinity between the two layers of the bi-layer.

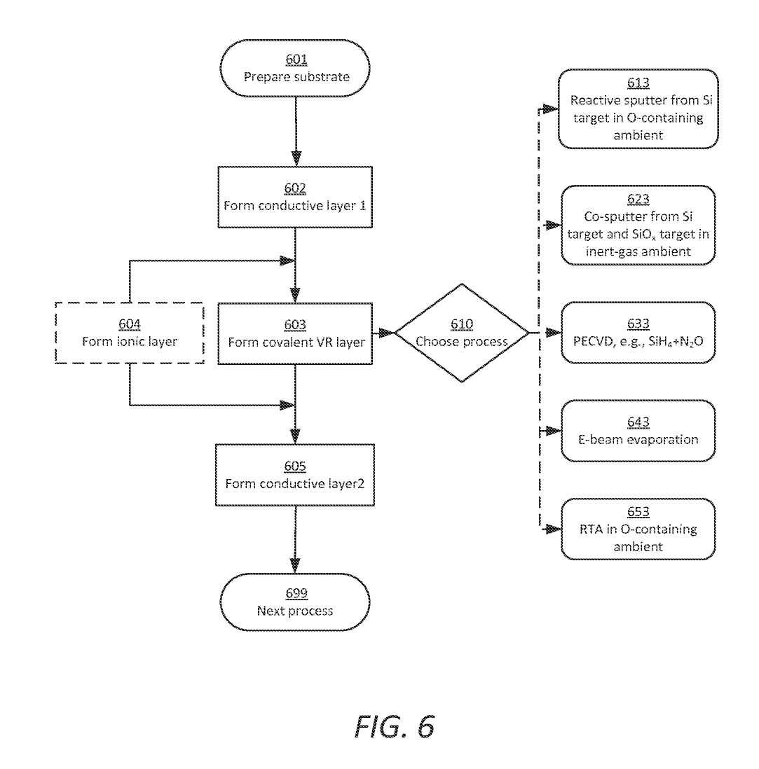

FIG. 6 is a flowchart of an example method for making a ReRAM cell with a covalent switching layer. Step 601 of preparing the substrate may include cleaning, degassing, other treatments, or the formation of layers and structures that precede those formed by this process. Step 602 of forming a first conductive layer may include PVD, CVD, ALD, electrodeposition, evaporation, or any other suitable deposition method for the material being used.

Step 603 of forming a covalent variable-resistance layer may include PVD, PECVD, electron-beam evaporation, or rapid thermal annealing. Options for forming the covalent layer, depicted by alternate-process branches from process decision 610, include step 613 of reactive sputtering from a silicon target in an oxygen-containing ambient; step 623 of co-sputtering from a silicon target and a silicon-oxide target in an inert-gas ambient; step 633 of PECVD using silane and nitrous oxide; step 643 of electron-beam evaporation; or step 653 of rapid thermal annealing of amorphous silicon in an oxygen-containing ambient.

For example: Either of the PVD sputtering methods may use a substrate temperature between 400C and 520C. The PECVD may use a 30-35 MHz RF plasma, a 3-to-5 sccm flow rate of silane, an 18-to-22-sccm flow rate of nitrous oxide, and a substrate temperature between 200C and 270C. The electron-beam evaporation may use a silicon target in a reactive oxygen environment or a silicon-oxide target in an inert environment and a substrate temperature between 100C and 150C. Rapid thermal annealing of amorphous silicon may include heating the substrate to between 520C and 620C for between 30 seconds and 30 minutes.

Step 604 of optionally forming a high-ionicity layer may include PVD, CVD, ALD, electrodeposition, evaporation, or any other suitable deposition method for the material being used. Step 605 of forming a second conductive layer may include PVD, CVD, ALD, electrodeposition, evaporation, or any other suitable deposition method for the material being used. Afterward, next process 699 may commence.

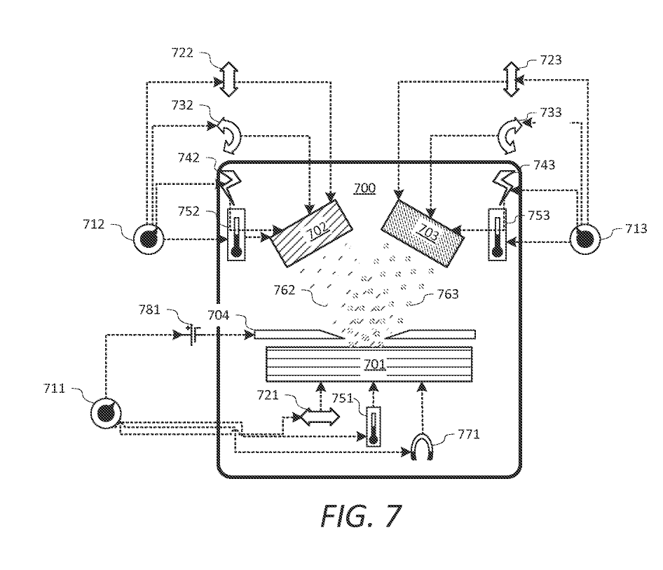

FIG. 7 is a block diagram of co-sputtering in an example PVD chamber. In chamber 700, substrate 701 receives a first sputtered material 762 from a first target 702 and a second sputtered material 763 from a second target 703. A controller 712 may control one or more of position 722, angle 732, plasma power 742, and temperature 752 of target 702. A controller 713 may control one or more of position 723, angle 733, plasma power 743, and temperature 753 of target 703. Although the illustrated system shows two targets for simplicity, some embodiments may use more than two targets.

Controllers 712 and 713 for the separate targets may independently vary the respective targets' position, angle, plasma power, or temperature in real time as sputtering continues. Thus the separate targets can be sputtered at different plasma power levels or temperatures, or from different throw distances to the substrate, to vary the relative concentrations of each target material being deposited on the substrate. If at least one of the variables can be changed while sputtering continues, the composition of the film may be varied with depth if desired.

Some process chambers also have a controller 711 to vary the position 721, temperature 751, and local magnetic field 771 of substrate 701. Like the other controllers 712 and 713, controller 711 may be programmable, may be remote from the process chamber and operate via a wireless connection, and may be capable of varying the substrate's position, angle, plasma power, or temperature in real time as sputtering continues. “Position” in this block diagram is symbolized by a single two-headed arrow for simplicity, but it is intended to symbolize position variation in any or all directions. Some process chambers also have a mask 704 to block sputtered materials 762, 763 from reaching selected parts of substrate 701. Optionally, a controllable bias voltage 781 may be applied to mask 704. In process chambers equipped to change the relative position of substrate 701 and mask 704 during processing, different parts of substrate 701 may be sputtered with material having different proportions of first material 762 and second material 763.

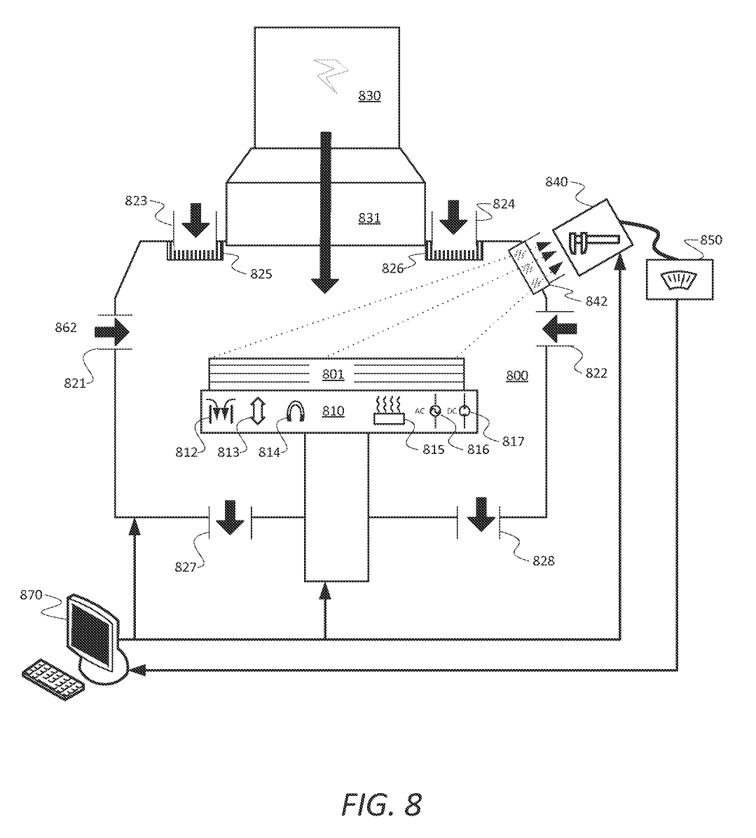

FIG. 8 is a block diagram of an example of a PECVD chamber. Inside chamber 800, substrate 801 is held by a substrate holder 810. Substrate holder 810 may be equipped with vacuum 812 (for example, a vacuum chuck to grip the substrate); motion 813 in any direction, which may include tilt and rotation; a magnetic field source 814; heater or temperature control 815; or sources of AC 816 or DC 817 bias voltage. Chamber 800 also has gas inlets 821, 822, 823, 824 for CVD precursors, buffer gases, and purge gases. Exhausts 827, 828 may be coupled to vacuum pumps to remove gases from chamber 800. Some of the inlets may feed through one or more diffusers or “showerheads” 825, 826.

In PECVD, the reaction that deposits material on substrate 801 involves reactive plasma species. In some embodiments, remote plasma chamber 830 may generate reactive species, such as ions, that enter chamber 800 through input adapter 831. In some embodiments, a direct plasma may be generated at or near the surface of substrate 801. Measurement system 840 may monitor substrate 801 through measurement ports 842. The measurements from measurement system 840 may be collected by a monitoring system 850.

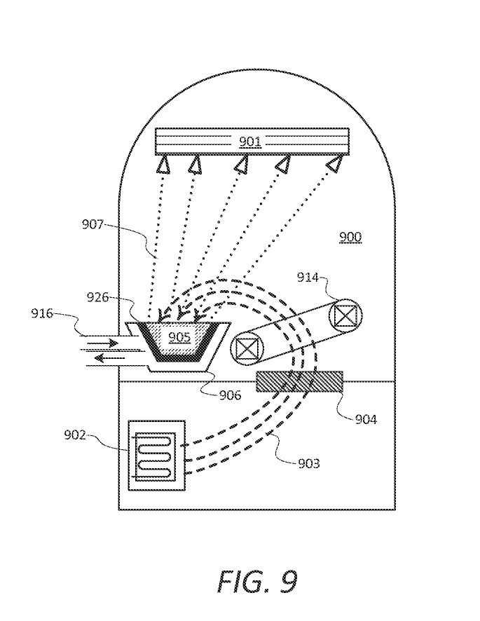

FIG. 9 is a block diagram of an example of an electron-beam evaporation tool. Substrate 901 is mounted upside-down in chamber 900. The material to be deposited on the downward-facing surface of substrate 101 is in target 905 mounted in crucible 906. Crucible 906 is typically water-cooled through conduits 916 and may hold target 905 in a graphite liner 926. A thermionic emitter 902 (e.g., a hot tungsten filament) emits electrons 903 in high-vacuum section 910 of chamber 900. Electrons 903 are focused by focusing magnet 904 and steered by deflecting magnet 914 to impact target 905. The electron impacts cause target material 907 to be ejected from target 905 and deposited on the downward-facing surface of substrate 901.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A device, comprising:
a substrate;
a first layer formed over the substrate, the first layer operable as a first electrode;
a second layer formed over the first layer, the second layer operable as a second electrode; and
a third layer formed between the first layer and the second layer;
wherein the third layer reversibly changes resistance responsive to a first write signal or a second write signal;
wherein a first write signal breaks covalent bonds in the third layer; and
wherein a second write signal re-forms broken covalent bonds in the third layer.

2. The device of claim 1, wherein the third layer comprises silicon and at least one of oxygen or nitrogen.

3. The device of claim 1, wherein a portion of the third layer near an interface is heated to between 500C and 900C by the second write signal, as calculated from thermal conductivities of the interface materials, a reset pulse current, a reset pulse length, and a cross-sectional area of a conductive filament at the interface.

4. The device of claim 1, further comprising a fourth layer formed between the first layer and the second layer;
wherein a dielectric constant of the fourth layer is greater than or equal to 9.

5. The device of claim 4, wherein the fourth layer has a stoichiometric composition.

6. The device of claim 4, wherein the third layer comprises a silicon oxide or a silicon oxynitride; and wherein the fourth layer comprises a transition metal oxide or a transition metal oxynitride.

7. The device of claim 4, wherein the third layer comprises a silicon nitride; and wherein the fourth layer comprises a transition metal nitride.

8. The device of claim 4, wherein a portion of the third layer near an interface with the fourth layer is heated to between 500C and 900C by the second write signal, as calculated from thermal conductivities of the interface materials, a reset pulse current, a reset pulse length, and a cross-sectional area of a conductive filament at the interface.

9. The device of claim 1, wherein the covalent bonds comprise silicon-silicon bonds.

10. A method, comprising:
forming a first layer over a substrate;
forming a second layer over the first layer;
forming a third layer over the second layer; and
forming a fourth layer over the third layer;
wherein the first layer is operable as a first electrode;
wherein the second layer comprises a sub-stoichiometric covalent-bonded silicon oxide, silicon nitride or silicon oxynitride;
wherein the third layer has a dielectric constant greater than 9;
wherein the fourth layer is operable as a second electrode; and
wherein a thickness of the second layer is between about 5 nm and about 10 nm.

11. The method of claim 10, wherein the forming of the second layer comprises physical vapor deposition at a substrate temperature between 400C and 520C.

12. The method of claim 11, wherein the forming of the second layer comprises reactive sputtering from a silicon target in an oxygen-containing ambient.

13. The method of claim 11, wherein the forming of the second layer comprises co-sputtering from a silicon target and a silicon-oxide target in an inert-gas ambient.

14. The method of claim 10, wherein the forming of the second layer comprises plasma-enhanced chemical vapor deposition at a substrate temperature between 200C and 270C.

15. The method of claim 14, wherein a gas mixture used for the plasma-enhanced chemical vapor deposition comprises silane and nitrous oxide.

16. The method of claim 14, wherein a plasma used for the plasma-enhanced chemical vapor deposition comprises a 30-35 MHz radio-frequency plasma.

17. The method of claim 10, wherein the forming of the second layer comprises electron-beam evaporation at a substrate temperature between 100C and 150C.

18. The method of claim 10, wherein the forming of the second layer comprises rapid thermal annealing of amorphous silicon in an oxygen-containing ambient.

19. The method of claim 18, wherein a substrate temperature during the rapid thermal annealing is between 520C and 620C.

20. The method of claim 18, wherein a duration of the rapid thermal annealing is between 30 seconds and 30 minutes.
